(19) United States
(12) Patent Application Publication
(10) Pub. No.: US 2025/0336425 A1
(43) Pub. Date: Oct. 30, 2025

(54) MAGNETIC MEMORY APPARATUS INCLUDING A MAGNETIC TUNNEL JUNCTION STRUCTURE

(71) Applicant: SAMSUNG ELECTRONICS CO., LTD., SUWON-SI (KR)

(72) Inventors: Shinhee HAN, Suwon-si (KR); Giwoong KWON, Suwon-si (KR); Heeho KIM, Suwon-si (KR); Boyoung SEO, Suwon-si (KR)

(21) Appl. No.: 18/977,157

(22) Filed: Dec. 11, 2024

(30) Foreign Application Priority Data
Apr. 24, 2024 (KR) 10-2024-0054986

(51) Int. Cl. G11C 5/06; H10B 61/00; H10N 50/10

(52) U.S. Cl. CPC G11C 5/063; H10B 61/22; H10N 50/10

(57) ABSTRACT

A magnetic memory apparatus includes: a plurality of bit lines; a plurality of source lines arranged at a different vertical level from the plurality of bit lines; and a plurality of memory cells connected between the bit lines and the source lines and each including a memory device and a selection transistor, wherein each of the plurality of memory cells includes a first memory cell, which includes a first memory device, and a second memory cell, which includes a second memory device. Each of the first memory device and the second memory device includes a magnetic tunnel junction including a pinned layer, a tunnel barrier layer, and a free layer. Each of the second memory devices includes a first dummy device, a second dummy device, and an active device located between the first dummy device and the second dummy device.

### CROSS-REFERENCE TO RELATED APPLICATION

This application claims priority under 35 U.S.C. § 119 to Korean Patent Application No. 10-2024-0054986, filed on Apr. 24, 2024, in the Korean Intellectual Property Office, the disclosure of which is incorporated by reference herein in its entirety.

### TECHNICAL FIELD

The present inventive concept relates to a magnetic memory apparatus, and more particularly, to a magnetic memory apparatus including a magnetic tunnel junction (MTJ) structure.

### DISCUSSION OF THE RELATED ART

Research has been conducted on electronic apparatuses that utilize the magnetoresistive properties of MTJs. For example, as MTJ cells of highly integrated magnetic random access memory (MRAM) apparatuses become miniaturized, fast read/write operations and low operating voltages of semiconductor apparatuses that are embedded in electronic products become more desirable. According to these demands, much research has been conducted on magnetic memory apparatuses that utilize the magnetoresistive properties of MTJs. For example, highly integrated magnetic memory apparatuses have been under development to provide high-speed read and write operations as a non-volatile memory device.

### SUMMARY

According to an embodiment of the present inventive concept, a magnetic memory apparatus includes: a plurality of bit lines; a plurality of source lines arranged at a different vertical level from the plurality of bit lines; and a plurality of memory cells connected between the bit lines and the source lines and each including a memory device and a selection transistor, wherein each of the plurality of memory cells includes a first memory cell, which includes a first memory device, and a second memory cell, which includes a second memory device, each of the first memory device and the second memory device includes a magnetic tunnel junction including a pinned layer, a tunnel barrier layer, and a free layer, in some of the second memory devices, the magnetic tunnel junction has an irreversible resistance state due to insulation breakdown of the tunnel barrier layer, each of the second memory devices includes a first dummy device, a second dummy device, and an active device located between the first dummy device and the second dummy device, and a spacing between the first dummy device and the active device in a first horizontal direction is substantially equal to a spacing between the second dummy device and the active device.

According to an embodiment of the present inventive concept, a magnetic memory apparatus includes: a substrate having a first area and a second area; a plurality of first memory devices and a plurality of second memory devices that each constitute a memory cell and are spaced apart from each other in a first horizontal direction, in the first area; an inter-wiring insulating layer located in the second area and having at least a portion located at a substantially same vertical level as the first memory devices and the second memory devices; capping layer patterns covering sidewalls of the plurality of first memory devices and the second memory devices; and buried layer patterns covering the capping layer patterns and filling a portion of each of spaces between the plurality of first memory devices and between the plurality of second memory devices, in the first area, wherein each of the plurality of first memory devices and the plurality of second memory devices includes a magnetic tunnel junction including a pinned layer, a tunnel barrier layer, and a free layer, in some of the plurality of second memory devices, the magnetic tunnel junction has an irreversible resistance state due to insulation breakdown of the tunnel barrier layer, each of the second memory devices each includes a first dummy device, a second dummy device, and an active device located between the first dummy device and the second dummy device, a spacing between the first dummy device and the active device in the first horizontal direction is substantially equal to a spacing between the second dummy device and the active device, and the spacing between the active device and the first dummy device in the first horizontal direction is substantially equal to a spacing between the plurality of first memory devices in the first horizontal direction.

According to an embodiment of the present inventive concept, a magnetic memory apparatus includes: a substrate having a cell array area and a peripheral circuit area; a separating insulation layer located in the cell array area and the peripheral circuit area; a plurality of first memory devices and a plurality of second memory devices that are located on the separating insulation layer in the cell array area, wherein the plurality of first memory devices and the plurality of second memory devices constitute a plurality of memory cells, and are spaced apart from each other in a horizontal direction; an inter-wiring insulating layer located in the peripheral circuit area and having at least a portion located at a substantially same vertical level as the plurality of first memory devices and the plurality of the second memory devices; capping layer patterns covering sidewalls of the plurality of first memory devices and the plurality of second memory devices; and buried layer patterns covering the capping layer patterns and filling a portion of each of spaces that are between the plurality of first memory devices and between the plurality of second memory devices, in the cell array area, wherein each of the plurality of first memory devices and the plurality of second memory devices includes a magnetic tunnel junction including a pinned layer, a tunnel barrier layer, and a free layer, in some of the plurality of second memory devices, the magnetic tunnel junction has an irreversible resistance state due to insulation breakdown of the tunnel barrier layer, each of the plurality of second memory devices includes a first dummy device, a second dummy device, and an active device located between the first dummy device and the second dummy device, a spacing between the first dummy device and the active device in a first horizontal direction is substantially equal to a spacing between the second dummy device and the active device, the spacing between the active device and the first dummy device in the first horizontal direction is substantially equal to a spacing between the plurality of first memory devices in the first horizontal direction, a greatest length of the active device in the first horizontal direction is less than a greatest length of the first memory devices in the first horizontal direction, and a greatest length of the first dummy device in the first horizontal direction is less than a greatest length from among lengths of the first memory devices in the first horizontal direction.

### BRIEF DESCRIPTION OF THE DRAWINGS

The above and other aspects of the present inventive concept will become more apparent by describing in detail embodiments thereof, with reference to the accompanying drawings, in which:

FIG. 1A is a configuration diagram showing a magnetic memory apparatus having a variable resistance device according to an embodiment of the present inventive concept;

FIG. 1B is a circuit diagram showing a cell array of a variable resistance device according to an embodiment of the present inventive concept;

FIG. 2 is a configuration diagram showing each memory cell provided in the memory cell array of FIG. 1A;

FIGS. 3A and 3B are conceptual diagrams showing data stored in a magnetization direction in a magnetic tunnel junction (MTJ) structure of the memory cell of FIG. 2;

FIG. 4 is a conceptual diagram showing a magnetization direction by using a write operation in the MTJ structure of the memory cell of FIG. 2;

FIGS. 5A, 5B, 6, 7A, and 7B are conceptual diagrams of the MTJ structure of the memory cell of FIG. 2, according to embodiments of the present inventive concept;

FIG. 8A is a cross-sectional view illustrating a magnetic memory apparatus according to an embodiment of the present inventive concept;

FIGS. 8B, 8C and 8D are enlarged views of area A of FIG. 8A according to embodiments of the present inventive concept;

FIG. 9 is a block diagram of an information processing system including a magnetic memory apparatus according to an embodiment of the present inventive concept;

FIG. 10 is a block diagram of an electronic system including a magnetic memory apparatus according to an embodiment of the present inventive concept;

FIG. 11 is a block diagram of a memory card including a magnetic memory apparatus according to an embodiment of the present inventive concept;

FIG. 12 is a block diagram of an electronic device including a magnetic memory apparatus according to an embodiment of the present inventive concept; and

FIG. 13 is a block diagram of a server system including a magnetic memory apparatus according to an embodiment of the present inventive concept.

### DETAILED DESCRIPTION OF THE EMBODIMENTS

Embodiments of the present inventive concept may be modified in various ways and may take various other forms, and embodiments of the present inventive concept will be illustrated in the drawings and described in detail herein. However, this disclosure and the drawings are not intended to limit the embodiments to the certain forms disclosed herein. The embodiments described below are merely illustrative, and various modifications are possible from the embodiments.

The use of all examples or illustrative terms is simply for explaining the technical spirit in detail, and the scope is not limited by these examples or illustrative terms unless limited by the claims.

Unless otherwise described below, in this specification, a vertical direction is defined as a Z direction, and a first direction and a second direction may each be defined as horizontal directions that are substantially perpendicular to the Z direction. The first direction may be referred to as X and the second direction may be referred to as Y. A vertical level may refer to a height level in a vertical direction Z. A horizontal width may refer to a length in a horizontal direction X and/or Y, and a vertical length may refer to a length in the vertical direction Z.

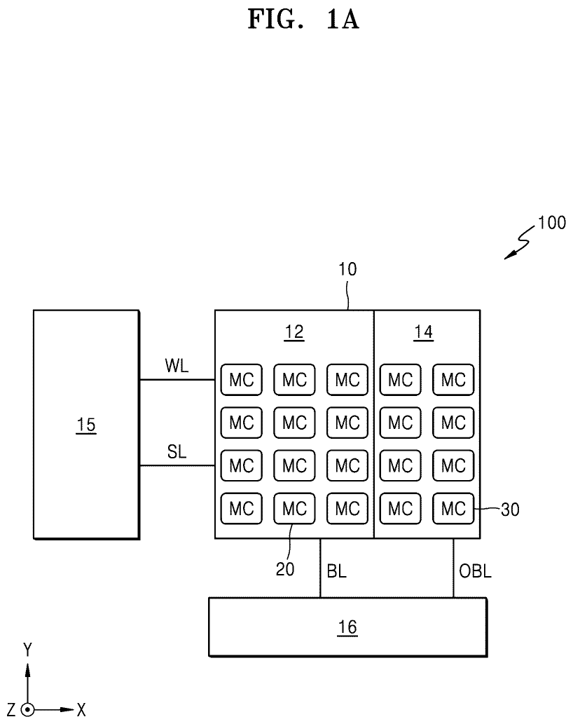

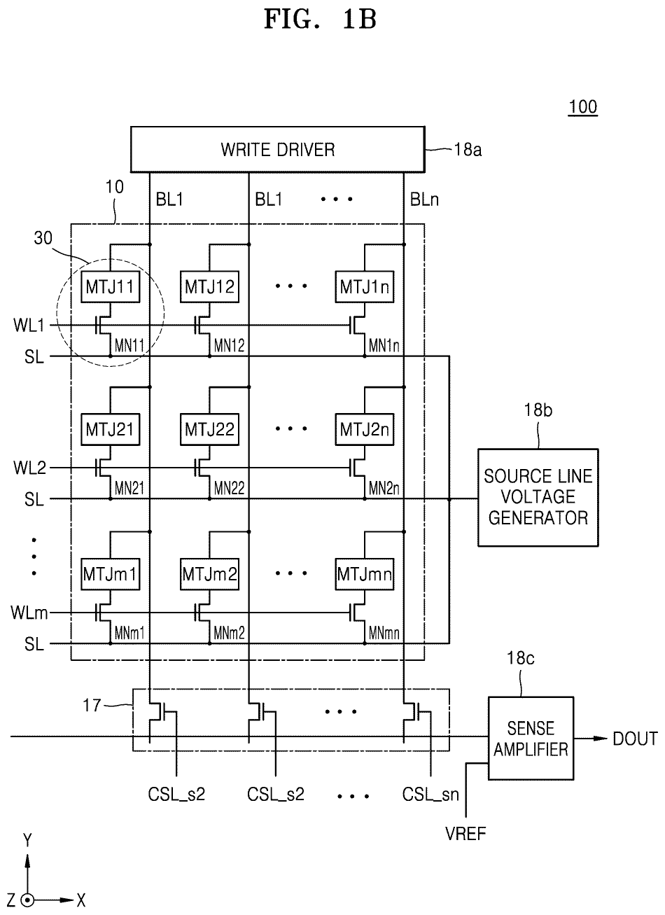

FIG. 1A is a configuration diagram showing a magnetic memory apparatus having a variable resistance device according to an embodiment of the present inventive concept.

Referring to FIG. 1A, the magnetic memory apparatus 100 may include a memory cell array 10, an address decoder circuit 15, and a data input/output circuit 16.

The memory cell array 10 includes a plurality of memory cells MC arranged in rows and columns. The plurality of memory cells MC may include magnetic memory cells including variable resistance devices. For example, the magnetic memory apparatus 100 may include a magneto resistive random access memory (MRAM) that includes an upper electrode of a magnetic material, a lower electrode of a magnetic material, and a dielectric disposed between the upper electrode and the lower electrode.

In the magnetic memory apparatus 100, each of the memory cells MC may include a selection transistor and a variable resistor implemented as a magnetic tunnel junction (MTJ). The memory cell array 10 includes a plurality of word lines WL, a plurality of bit lines BL and OBL, and a plurality of source lines SL, which are connected to the memory cells MC. Each of the word lines WL is connected to a gate of a selection transistor of the memory cells MC that is located in one of the rows, and each of the bit lines BL and the source lines SL is connected to a variable resistor and a source of the selection transistor of the memory cells MC that is located in one of the columns.

The memory cell array 10 includes a normal memory cell array 12 and a one time programmable (OTP) memory cell array 14.

The normal memory cell array 12 includes a plurality of normal memory cells 20, and each of the plurality of normal memory cells 20 includes a first selection transistor and a first variable resistance device. The normal memory cell array 12 includes the first selection transistor, which is connected to each of the plurality of word lines WL in one-to-one correspondence with rows, and the first variable resistance device, which is connected to each of the plurality of bit lines BL in one-to-one correspondence with columns.

The OTP memory cell array 14 includes a plurality of OTP memory cells 30, and the OTP memory cell 30 includes a second selection transistor and a second variable resistance device. The OTP memory cell 30 may have the same structure as the normal memory cell 20. The OTP memory cell array 14 may include a second selection transistor, which is connected to each of the plurality of word lines WL, and a second variable resistance device, which is connected to an OTP bit line OBL corresponding to one of the columns, and the second variable resistance device may be short-circuited. For example, the second variable resistance device of the OTP memory cell 30 may have an irreversible resistance state by applying a breakdown voltage (BV) in one programming operation to electrically breakdown a tunnel barrier layer.

As a peripheral circuit of the memory cell array 10, the magnetic memory apparatus 100 may include the address decoder circuit 15 and the data input/output circuit 16.

The address decoder circuit 15 may be connected to the memory cell array 10 through the word lines WL and the source lines SL. The address decoder circuit 15 may decode a row address to select the word lines WL and the source lines SL and decode a column address to select the bit lines BL.

The data input/output circuit 16 may be connected to the memory cell array 10 through the bit lines BL and OBL. The data input/output circuit 16 may include a column selection circuit, a write driver circuit, and a sense amplifier circuit. In the column selection circuit, one of the bit lines BL is selected in response to a column selection signal provided from the address decoder circuit 15, and a predetermined read/write voltage is applied to the bit line BL that is selected by the column selection circuit through the write driver circuit by using the read/write operation. The sense amplifier circuit determines data of the normal memory cell 20 in the normal memory cell array 12.

FIG. 1B is a circuit diagram showing a cell array of a variable resistance device according to an embodiment of the present inventive concept.

Referring to FIG. 1B, the magnetic memory apparatus 100 may include a magnetoresistive memory cell array 10. The magnetoresistive memory cell array 10 may also be referred to as the OTP memory cell array described in FIG. 1A. The magnetoresistive memory cell array 10 may be connected to a write driver 18a, a selection circuit 17, a source line voltage generator 18b, and a sense amplifier 18c. The magnetoresistive memory cell array 10 may include a plurality of magnetoresistive memory cells 30. The magnetoresistive memory cell 30 may be referred to as the OTP memory cell described in FIG. 1B. The magnetoresistive memory cell array 10 may include a plurality of word lines WL1 to WLm and a plurality of bit lines BL1 to BLn. The magnetoresistive memory cell array 10 may have a magnetoresistive memory cell 30 between each of the word lines WL1 to WLm and each of the bit lines BL1 to BLn. For example, each of the magnetoresistive memory cells 30 may be adjacent to an intersection between the plurality of word lines WL1 to WLm and the plurality of bit lines BL1 and BLn.

The magnetoresistive memory cell array 10 may include cell transistors MN11 to MNmn, which have gates connected to the word lines WL1 to WLm, and magnetic tunnel junction layers MTJ11 to MTJmn, which are connected between each of the cell transistors MN11 to MNmn and each of the bit lines BL1 to BLn and constitute a variable resistance layer.

Respective sources of the cell transistors MN11 to MN1mn may be connected to a source line SL. The selection circuit 17 may selectively connect the bit lines BL1 to BLn to the sense amplifier 18c in response to column selection signals CSL_s1 to CSL_sn. The sense amplifier 18c may generate output data DOUT by amplifying a difference between an output voltage signal of the selection circuit 17 and a reference voltage VREF.

The write driver 18a is connected to the bit lines BL1 to BLn, generates a program current based on write data, and provides the program current to the bit lines BL1 to BLn. To magnetize the magnetic tunnel junction layers MTJ11 to MTJmn in the magnetoresistive memory cell array 10, a voltage, which is higher than the voltage that is applied to the bit lines BL1 to BLn, may be applied to the source line SL. The source line voltage generator 18b may generate a source line driving voltage VSL and provide the source line driving voltage VSL to the source lines of the magnetoresistive memory cell array 10.

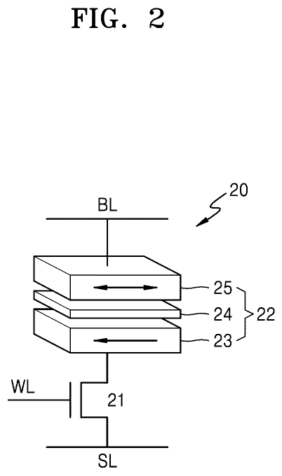

FIG. 2 is a configuration diagram showing each memory cell provided in the memory cell array of FIG. 1A.

Referring to FIG. 2, the normal memory cell 20 is shown from among memory cells MC (see FIG. 1A) that are provided in the memory cell array 10 (see FIG. 1A).

The normal memory cell 20 includes a selection transistor 21 and an MTJ structure 22. A gate of the selection transistor 21 may be connected to the word line WL, and a drain electrode of the selection transistor 21, which is one electrode of the selection transistor 21, may be connected to the bit line BL through the MTJ structure 22. A source electrode of the selection transistor 21, which is another electrode of the selection transistor 21, may be connected to the source line SL.

The MTJ structure 22 may include a pinned layer 23, a free layer 25, and a tunnel barrier layer 24 disposed between the pinned layer 23 and the free layer 25. A magnetization direction of the pinned layer 23 may be fixed, and a magnetization direction of the free layer 25 may be parallel (P) or anti-parallel (AP) to the magnetization direction of the pinned layer 23 depending on data that is stored by the write operation. To fix the magnetization direction of the pinned layer 23, an anti-ferromagnetic layer may be further provided.

The pinned layer 23 may include a ferromagnetic material. For example, the pinned layer 23 may include at least one of CoFeB, Fe, Co, Ni, Gd, Dy, CoFe, NiFe, MnAs, MnBi, MnSb, CrO, MnOFeO, FeOFeO, NiOFeO, CuOFeO, MgOFeO, EuO, and/or YFeO.

The tunnel barrier layer 24 may include a non-magnetic material. For example, the tunnel barrier layer 24 may include at least one of magnesium (Mg), titanium (Ti), aluminum (Al), magnesium zinc oxide (MgZnO), titanium nitride (TiN), and/or vanadium nitride (VN).

For example, the free layer 25 may include a ferromagnetic material including at least one of cobalt (Co), iron (Fe), and/or nickel (Ni). For example, the free layer 25 may include at least one of FeB, Fe, Co, Ni, Gd, Dy, CoFe, NiFe, MnAs, MnBi, MnSb, CrO, MnOFeO, FeOFeO, NiOFeO, CuOFeO, MgOFeO, EuO, and/or YFeO.

In embodiments of the present inventive concept, when the free layer 25 and the pinned layer 23 of the MTJ structure 22 are in a parallel (P) state, that is, when the MTJ structure 22 has a low resistance, the normal memory cell 20 may be defined as a data 0 (zero) logic state. In addition, when the free layer 25 and the pinned layer 23 of the MTJ structure 22 are in an anti-parallel (AP) state, that is, when the MTJ structure 22 a has high resistance, the normal memory cell 20 may be defined as a data 1 (one) logic state. In embodiments of the present inventive concept, the normal memory cell 20 may be defined as a data 0 logic state in the anti-parallel (AP) state of the MTJ structure 22 and may be defined as a data 1 logic state in the parallel (P) state.

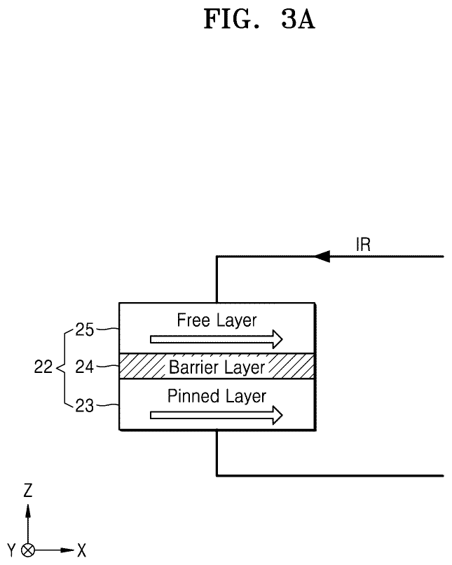

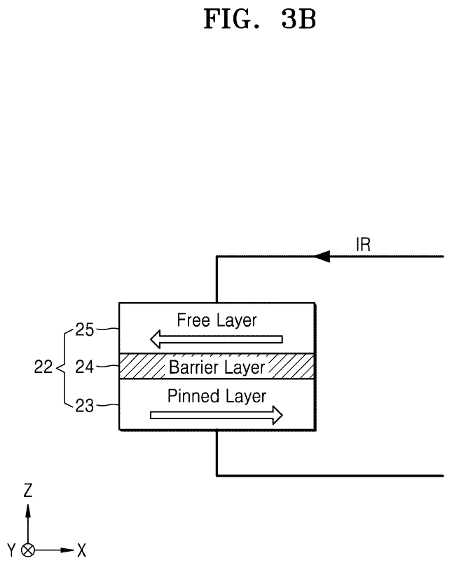

FIGS. 3A and 3B are conceptual diagrams showing data stored in a magnetization direction in the MTJ structure of the memory cell of FIG. 2.

Referring to FIGS. 3A and 3B, a resistance value of the MTJ structure 22 may vary depending on the magnetization direction of the free layer 25.

When a read current IR flows through the MTJ structure 22, a data voltage depending on the resistance value of the MTJ structure 22 may be output. Since the intensity of the read current IR is much less than the intensity of a write current, the magnetization direction of the free layer 25 does not change due to the read current IR.

As shown in FIG. 3A, in the MTJ structure 22, the magnetization direction of the free layer 25 and the magnetization direction of the pinned layer 23 may be arranged in parallel to each other. The MTJ structure 22 in this state may have a low resistance value, and data 0 may be output through a read operation.

As shown in FIG. 3B, in the MTJ structure 22, the magnetization direction of the free layer 25 and the magnetization direction of the pinned layer 23 may be arranged in anti-parallel to each other. The MTJ structure 22 in this state may have a high resistance value, and data 1 may be output through a read operation.

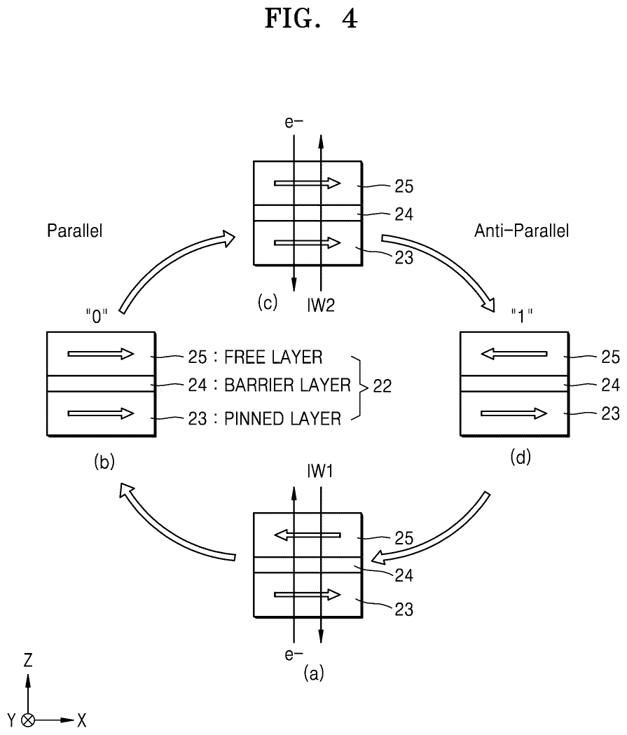

FIG. 4 is a conceptual diagram showing a magnetization direction by using a write operation in the MTJ structure of the memory cell of FIG. 2.

Referring to FIG. 4, the magnetization direction of the free layer 25 may be determined depending on a direction of write currents IW1 and IW2 flowing through the MTJ structure 22.

When the first write current IW1 is applied from the free layer 25 toward the pinned layer 23 as shown in (a), free electrons having the same spin direction as the pinned layer 23 may exert a torque on the free layer 25. Thus, the free layer 25 may be magnetized parallel to the pinned layer 23. Therefore, data 0 with a low resistance value may be stored in the MTJ structure 22 as shown in (b).

In the MTJ structure 22 in the data 0 state, when the second write current IW2 is applied from the pinned layer 23 to the free layer 25 as shown in (c), free electrons having an opposite spin direction to the pinned layer 23 return to the free layer 25 and may exert a torque on the free layer 25. Thus, the free layer 25 may be magnetized anti-parallel to the pinned layer 23. Therefore, data 1 with a high resistance value may be stored in the MTJ structure 22 as shown in (d).

For example, the magnetization direction of the free layer 25 in the MTJ structure 22 may be changed to be parallel or anti-parallel to the pinned layer 23 by spin transfer torque (STT), and accordingly, data 0 or data 1 may be stored.

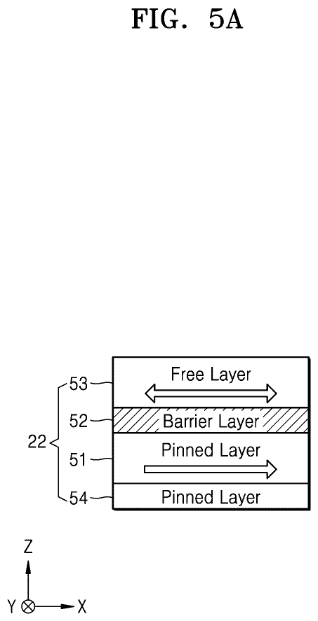

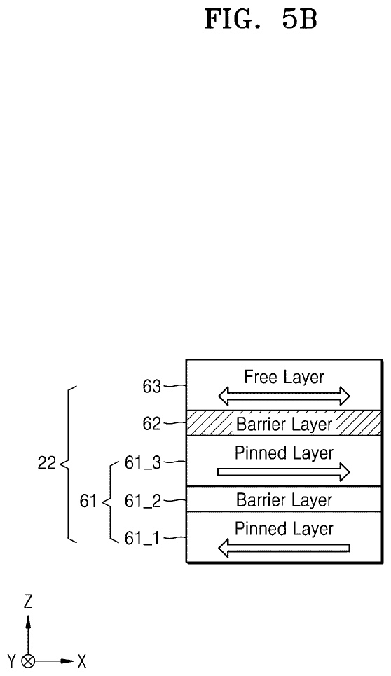

FIGS. 5A to 7B are conceptual diagrams of the MTJ structure of the memory cell of FIG. 2, according to embodiments of the present inventive concept.

Referring to FIG. 5A, the MTJ structure 22 may include a pinned layer 51, a tunnel barrier layer 52, a free layer 53, and an anti-ferromagnetic layer 54.

The anti-ferromagnetic layer 54 may include an anti-ferromagnetic material. For example, the anti-ferromagnetic layer 54 may include at least one of PtMn, IrMn, MnO, MnS, MnTe, MnF, FeCl, FeO, CoCl, CoO, NiCl, NiO, and/or Cr.

The free layer 53 and the pinned layer 51 of the MTJ structure 22 may each include a ferromagnetic, and thus, a stray field may be generated at an edge of the ferromagnetic. The stray field may lower a magnetic resistance or increase a magnetic resistance of the free layer 53. For example, the stray field may affect switching characteristics, forming asymmetric switching. Therefore, there may be a desire for a structure that reduces or controls the stray field that may be generated from the ferromagnetic in the MTJ structure 22.

Referring to FIG. 5B, the MTJ structure 22 may include a pinned layer 61, a tunnel barrier layer 62, and a free layer 63, and the pinned layer 61 may include a synthetic anti-ferromagnetic.

The pinned layer 61 may include a first ferromagnetic layer 61_1, a coupling layer 61_2, and a second ferromagnetic layer 61_3. For example, each of the first and second ferromagnetic layers 61_1 and 61_3 may include at least one of CoFeB, Fe, Co, Ni, Gd, Dy, CoFe, NiFe, MnAs, MnBi, MnSb, CrO, MnOFeO, FeOFeO, NiOFeO, CuOFeO, MgOFeO, EuO, and/or YFeO. For example, the coupling layer 61_2 may include ruthenium (Ru).

The magnetization direction of the first ferromagnetic layer 61_1 and the magnetization direction of the second ferromagnetic layer 61_3 may be different directions from each other, and each magnetization direction may be fixed.

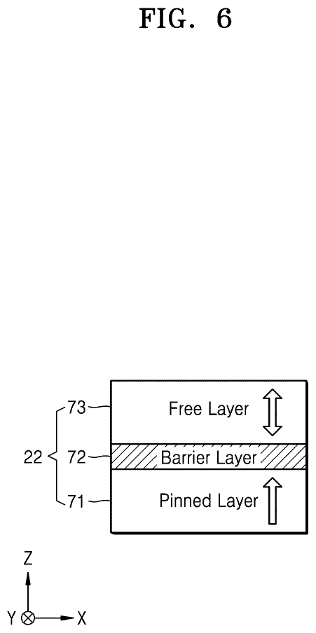

Referring to FIG. 6, the magnetization direction of the MTJ structure 22 may be substantially perpendicular to a tunnel barrier layer 72, and accordingly, a direction of current movement and an easy axis of magnetization may be substantially parallel to each other.

A structure in which magnetization directions are substantially perpendicular is called a perpendicular MTJ structure. The perpendicular MTJ structure 22 also includes a pinned layer 71, the tunnel barrier layer 72, and a free layer 73. When a magnetization direction of the free layer 73 and a magnetization direction of the pinned layer 71 are parallel to each other, a resistance value may decrease, and when the magnetization direction of the free layer 73 and the magnetization direction of the pinned layer 71 are antiparallel to each other, the resistance value may increase. Therefore, data may be stored in the perpendicular MTJ structure 22 depending on a resistance value.

To implement the perpendicular MTJ structure 22, the free layer 73 and the pinned layer 71 may include a material with high magnetic anisotropy energy. For example, each of the free layer 73 and the pinned layer 71 may include an ordered alloy and include at least one of iron (Fe), cobalt (Co), nickel (Ni), palladium (Pa), and/or platinum (Pt). Each of the free layer 73 and the pinned layer 71 may include at least one of Fe—Pt alloy, Fe—Pd alloy, Co—Pd alloy, Co—Pt alloy, Fe—Ni—Pt alloy, Co—Fe—Pt alloy, and/or Co—Ni—Pt alloy.

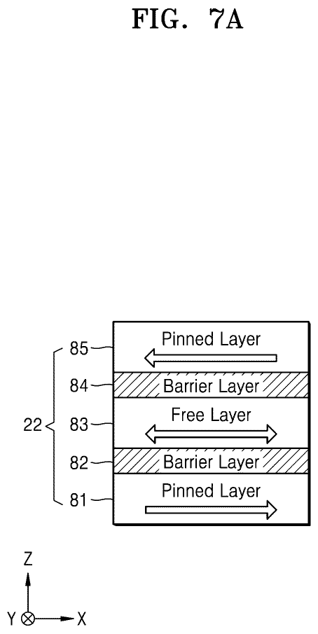

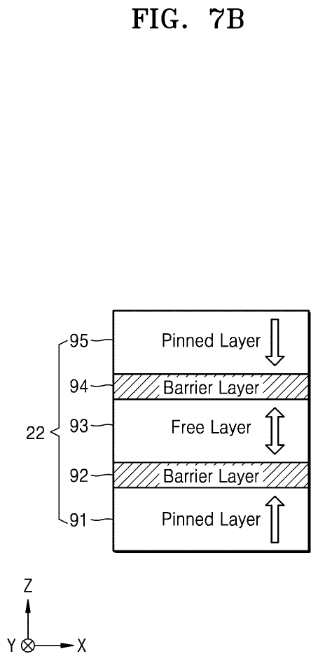

FIG. 7A shows a dual MTJ structure 22 in which tunnel barrier layers 82 and 84 and pinned layers 81 and 85 are respectively located at two sides (e.g., opposing sides) of the free layer 83.

The dual MTJ structure 22 forming horizontal magnetism may include a first pinned layer 81, the first tunnel barrier layer 82, the free layer 83, the second tunnel barrier layer 84, and the second pinned layer 85. The first and second pinned layers 81 and 85 may be similar to the pinned layer 51 (see FIG. 5A). The first and second tunnel barrier layers 82 and 84 may be similar to the tunnel barrier layer 52 (see FIG. 5A), and the free layer 83 may be similar to the free layer 53 (see FIG. 5A).

When a magnetization direction of the first pinned layer 81 and a magnetization direction of the second pinned layer 85 are fixed in opposite directions of each other, magnetic force caused by the first and second pinned layers 81 and 85 may be substantially canceled out. The dual MTJ structure 22 may perform a read operation by using less current than a typical MTJ device. The dual MTJ structure 22 may provide a higher resistance during the read operation due to the second tunnel barrier layer 84, and thus a clear resistance value may be obtained.

FIG. 7B shows a perpendicular dual MTJ structure 22 in which tunnel barrier layers 92 and 94 and pinned layers 91 and 95 are respectively located at two sides (e.g., opposing sides) of the free layer 93.

The vertical dual MTJ structure 22 forming vertical magnetism may include a first pinned layer 91, the first tunnel barrier layer 92, the free layer 93, the second tunnel barrier layer 94, and the second pinned layer 95. The first and second pinned layers 91 and 95 may be similar to the pinned layer 71 (see FIG. 6). The first and second tunnel barrier layers 92 and 94 may be similar to the tunnel barrier layer 72 (see FIG. 6), and the free layer 93 may be similar to the free layer 73 (see FIG. 6).

When a magnetization direction of the first pinned layer 91 and a magnetization direction of the second pinned layer 95 are fixed in opposite directions from each other, magnetic force caused by the first and second pinned layers 91 and 95 may be substantially canceled out. The perpendicular dual MTJ structure 22 may perform a read operation by using less current than a typical MTJ device. The perpendicular dual MTJ structure 22 may provide a higher resistance during the read operation due to the second tunnel barrier layer 94, and thus a clear resistance value may be obtained.

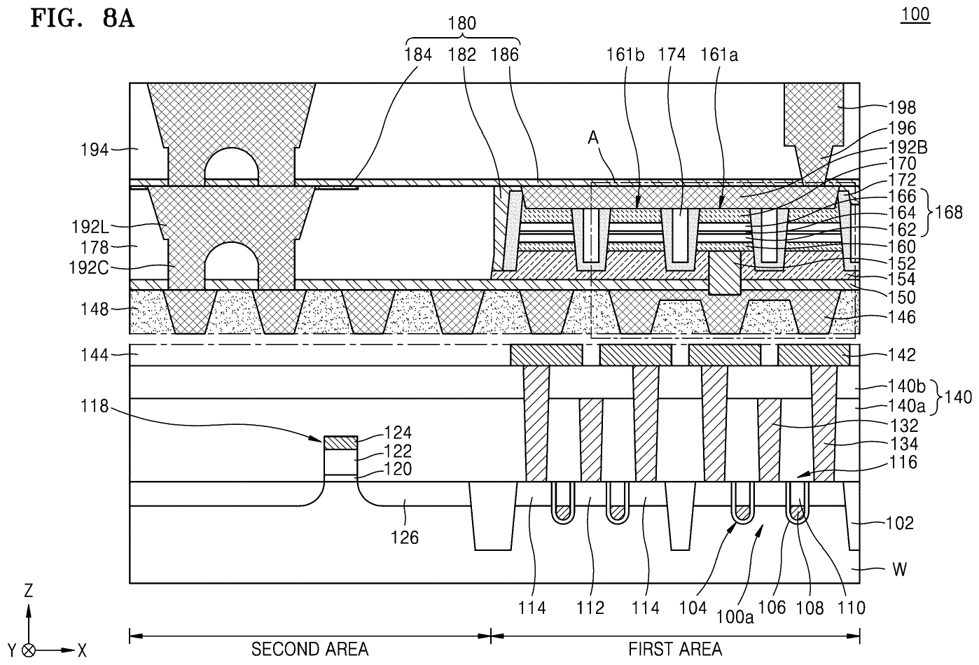

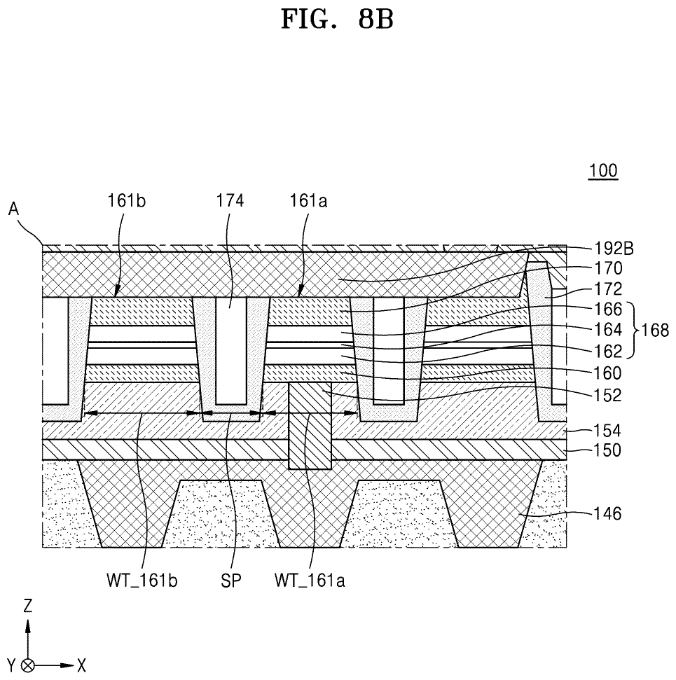

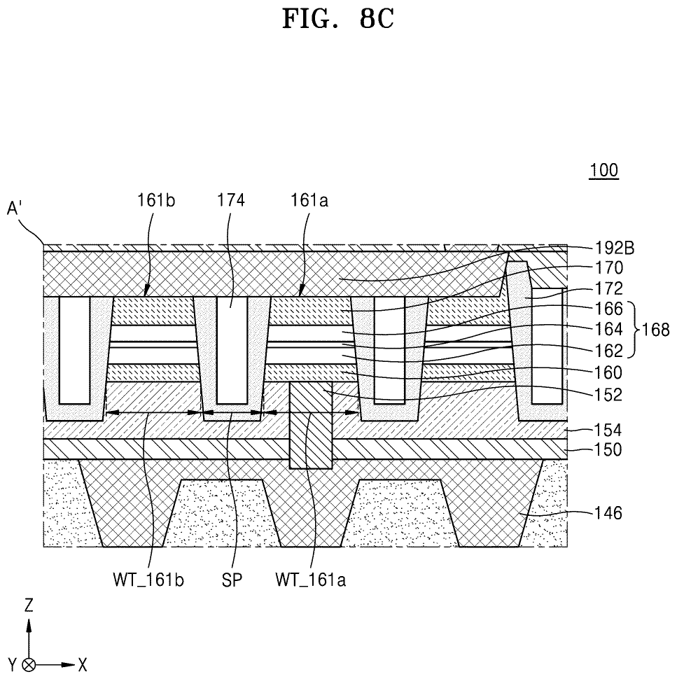

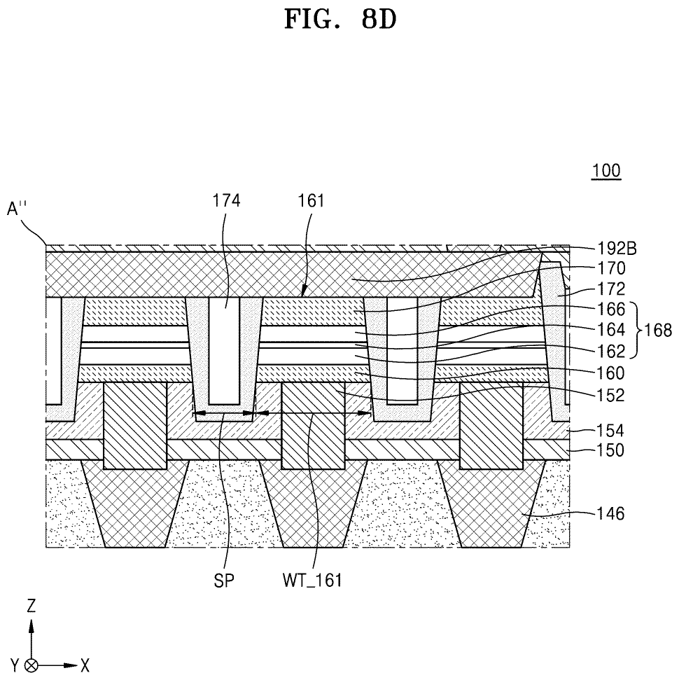

FIG. 8A is a cross-sectional view illustrating a magnetic memory apparatus according to an embodiment of the present inventive concept.

FIG. 8A is referenced together with FIGS. 1 to 7B. The magnetic memory apparatus 100 may include a substrate W that is divided into a first area and a second area. The first area may be a cell array area in which magnetoresistive memory cells are formed. The second area may be a peripheral circuit area that is located adjacent to the first area and in which core/ferry circuits are formed. In the first and second areas, the substrate W may include an active area 100a that is defined by a device isolation layer 102. In the cell array area, the magnetic memory apparatus 100 may include a plurality of bit lines BL, a plurality of source lines SL corresponding to the bit lines BL, and a plurality of memory cells that are connected between the bit lines and the source lines and including a memory device and a first transistor 116. The memory cell may include a first memory cell including a first memory device 161 (see FIG. 8) and a second memory cell including a second memory device.

The second memory device may include a first dummy device 161b, a second dummy device, and an active device 161a located between the first dummy device 161b and the second dummy device. A spacing SP between the first dummy device 161b and the active device 161a in a first horizontal direction X may be equal to a spacing SP between the second dummy device and the active device 161a. However, for convenience of explanation, FIG. 8A shows the magnetic memory apparatus 100 including the active device 161a and the dummy device 161b from among magnetoresistive memory cells. The first memory cells may constitute a normal memory cell array that is to be programmed multiple times, and the second memory cells may constitute a one time programmable (OTP) memory cell array that is to be programmed once.

The first transistor 116 may be provided in the active area 100a of the first area. The first transistor may correspond to the selection transistor 21 in FIG. 2. For example, two first transistors 116 including two first gate electrodes 108 may be formed in the active area 100a. For example, a first source area 112 may be formed in a central portion of the active area 100a. The first source area 112 may be a common source area that is shared by the two first transistors 116 formed in the active area 100a. The number of first transistors 116 shown in the common source area is not limited to the drawing. The number of selection transistors, that is, the first transistors 116, per unit memory cell may be greater in the second memory cell than in the first memory cell. For example, the first drain areas 114 may be formed at both edges of the active area 100a.

A source line 132 may be formed on the first source area 112 of the active area 100a. For example, the source line 132 may be in contact with an upper surface of the first source area 112. For example, the source line 132 may include at least one metal such as tungsten, titanium, and tantalum, or metal nitrides such as tungsten nitride, titanium nitride, and tantalum nitride.

Although FIG. 8A shows an example in which the first transistor 116 has a buried gate structure and in which a first gate electrode 108 is formed in a trench that extends into the substrate W, in embodiments of the present inventive concept, the first transistor 116 may include at least one of a finFET device, a gate all-around type FET device, or a planar type transistor device.

A second transistor 118 constituting core/peri circuits may be formed on the substrate W in the second area. In embodiments of the present inventive concept, the second transistor 118 may include a planar transistor. For example, the second transistor 118 may include a second gate insulating layer pattern 120, a second gate electrode 122, and a second source/drain area 126 that are formed on the substrate W in the second area. A second hard mask pattern 124 may cover the second gate electrode 122. The second gate insulating layer pattern 120, the second gate electrode 122, and the second hard mask pattern 124 may together be referred to as a second gate structure.

A first interlayer insulating layer 140 may be formed on the substrate W in the first area and the second area. The first interlayer insulating layer 140 may be formed to cover the source line 132, the first transistor 116, and the second transistor 118 with a sufficient thickness. In embodiments of the present inventive concept, the first interlayer insulating layer 140 may include a first lower interlayer insulating layer 140a and a second lower interlayer insulating layer 140b. The source line 132 may be formed to pass through the first lower interlayer insulating layer 140a.

In the first area, a contact plug 134 may be formed to pass through the first interlayer insulating layer 140 and may be in contact with the first drain area 114. The contact plug 134 may be formed to pass through the first lower interlayer insulating layer 140a and the second lower interlayer insulating layer 140b and may be in contact with the first drain area 114.

A first wiring line 142 may be provided on the contact plug 134. A first inter-wiring insulating layer 144 may be located between the first wiring lines 142. The first inter-wiring insulating layer 144 may at least partially surround the first wiring lines 142. For example, the first inter-wiring insulating layer 144 may include silicon oxide or an insulating material with a dielectric constant that is lower than that of silicon oxide. For example, the first inter-wiring insulating layer 144 may include a tetraethyl orthosilicate (TEOS) film, an ultra low K (ULK) film, or an extreme low-k (ELK) film. In embodiments of the present inventive concept, the ULK film or the ELK film may have a dielectric constant of about 2 to about 3.5. In embodiments of the present inventive concept, the first inter-wiring insulating layer 144 may include a SiOC film, a SiOF film, a SiCH film, a SiCOH film, or a combination thereof.

Metal wiring may be disposed on the first wiring lines 142. The metal wiring may include wiring lines and wiring contacts that are electrically connected to the selection transistor. According to an embodiment of the present inventive concept, first wiring contacts 146 may be provided as wiring contacts. The first wiring contacts 146 may be electrically connected to the corresponding first wiring lines 142. In embodiments of the present inventive concept, the first wiring contacts 146 may be in contact with the corresponding first wiring lines 142, but the present inventive concept is not limited thereto. For example, at least one wiring contact and at least one wiring line are located between each of the corresponding first wiring lines 142 and the first wiring contacts 146, and thus each of the first wiring lines 142 may be electrically connected to a corresponding first wiring contact 146 of the first wiring contacts 146 through the at least one wiring contact and the at least one wiring line. The first wiring contacts 146 located in the second area may be spaced apart from each other. For example, when each of the first wiring contacts 146 in the first area is electrically connected to the active device 161a, each of the first wiring contacts 146 may be connected to each other and integrated with one another to be a single body. The first wiring contact 146 might not be electrically connected to the dummy device 161b. Accordingly, the dummy device 161b may be connected to a bit line, but might not be connected to the source line. The active device 161a may be connected to the source line through metal wiring.

A second inter-wiring insulating layer 148 may be located between the first wiring contacts 146. The second inter-wiring insulating layer 148 may at least partially surround the first wiring contacts 146. The second inter-wiring insulating layer 148 may include, for example, silicon oxide or an insulating material with a dielectric constant that is lower than that of silicon oxide. In embodiments of the present inventive concept, the second inter-wiring insulating layer 148 may include a TEOS film, a ULK film, or an ELK film.

A separating insulation layer 150 may cover the first wiring contacts 146 and the second inter-wiring insulating layer 148. The separating insulation layer 150 may be disposed on the first wiring contacts 146 and the second inter-wiring insulating layer 148. The separating insulation layer 150 may include an insulating material that has a dielectric constant that is higher than that of silicon oxide but a dielectric constant that is lower than that of silicon nitride. In embodiments of the present inventive concept, the separating insulation layer 150 may include an insulating material other than oxide. For example, the separating insulation layer 150 may include SiCN. The separating insulation layer 150 may cover the first wiring contacts 146 and the second inter-wiring insulating layer 148 with a substantially constant thickness.

In the first area, lower electrode contacts 152 may be disposed on corresponding first wiring contacts 146. In the case of the OTP memory cell 30 (see FIG. 1A), the lower electrode contact 152 might not be disposed on each of lower surfaces of all magnetic tunnel junctions 168. According to an embodiment of the present inventive concept, the lower electrode contact 152 may be disposed on the lower surface of the active device 161a and not on the lower surface of the dummy device 161b. The lower electrode contacts 152 may be formed to pass through the separating insulation layer 150 and may be in contact with the corresponding first wiring contacts 146. For example, the lower electrode contact 152 may be provided when direct contact between the first wiring contact 146 and the active device 161a and the dummy device 161b is difficult. In embodiments of the present inventive concept, when the first wiring contact 146 and the active device 161a are in direct contact with each other, the lower electrode contact 152 might not be provided. In embodiments of the present inventive concept, the first wiring contact 146, which contacts the lower electrode contact 152 that is disposed on the lower surface of the active device 161a, may be the first wiring contact 146 that is formed by integrating the plurality of first wiring contacts 146. Although the drawing shows three first wiring contacts 146 formed as one body, the number of first wiring contacts 146 formed as one body is not limited to the drawing.

In the first area, a contact separation layer 154 may cover sidewalls of the lower electrode contacts 152 on the separating insulation layer 150. An upper surface of a portion of the contact separation layer 154, which is located between adjacent lower electrode contacts 152, may be located at a vertically lower level than an upper surface of a portion of the contact separation layer 154, which covers the sidewalls of the lower electrode contacts 152. For example, the contact separation layer 154 may conformally cover the upper surface of the separating insulation layer 150 and the sidewalls of the lower electrode contacts 152. For example, the contact separation layer 154 may include silicon oxide. For example, the contact separation layer 154 may include a TEOS film.

In the first area, the active device 161a constituting an OTP memory cell may be provided on the lower electrode contact 152. The active device 161a may have an isolated island shape. Although one active device 161a is shown in the drawing, a plurality of active devices 161a may be provided. The plurality of active devices 161a may be spaced apart from each other in a horizontal direction. For example, the active device 161a may be spaced apart from the dummy device 161b in a horizontal direction. The lower surface of the active device 161a may be in contact with the upper surface of the portion of the lower electrode contact 152 and the upper surface of the portion of the contact separation layer 154, which covers the sidewall of the lower electrode contact 152. The active device 161a may have a structure in which a lower electrode 160, the magnetic tunnel junction 168, and an upper electrode 170 are stacked. For example, the lower surface of the lower electrode 160 may be in contact with the upper surface of the portion of the lower electrode contact 152 and the upper surface of the portion of the contact separation layer 154, which covers the sidewall of the lower electrode contact 152.

The magnetic tunnel junction 168 may constitute a variable resistance layer and may include a pinned layer pattern 162, a tunnel barrier layer pattern 164, and a free layer pattern 166. The active device 161a may have a tapered shape, in which a horizontal width decreases away from the substrate W in a vertical direction (Z direction). For example, each of the lower electrode 160, which is provided in the active device 161a and the dummy device 161b, the magnetic tunnel junction 168, which includes the pinned layer pattern 162, the tunnel barrier layer pattern 164, and the free layer pattern 166, and the upper electrode 170 may have a tapered shape, in which a horizontal width decreases away from the substrate W in the vertical direction (Z direction).

The lower electrode 160 and upper electrode 170 may include metal or metal nitride. For example, the pinned layer pattern 162 may include iron manganese (FeMn), iridium manganese (IrMn), platinum manganese (PtMn), manganese oxide (MnO), manganese sulfide (MnS), manganese tellurium (MnTe), and manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), and chromium (Cr).

Buried layer patterns 174 may be formed on a capping layer pattern 172 to fill a portion of spaces that are between the lower electrode 160 and the upper electrodes 170. The buried layer pattern 174 may include, for example, silicon oxide. For example, the buried layer pattern 174 may include silicon oxide formed using a high density plasma (HDP) process. The uppermost end of the buried layer pattern 174 may be located at a vertically lower level than the uppermost end of the upper electrode 170, and the lowermost end of the buried layer pattern 174 may be located at a vertically higher level than the upper surface of the separating insulation layer 150.

In the first area, a first insulating stopper layer 182, of an insulating stopping structure 180, may be formed on the capping layer pattern 172 and the buried layer pattern 174. The first insulating stopper layer 182 may fill the remaining portion of the spaces between the active device 161a and the dummy device 161b on the capping layer pattern 172. For example, a lower portion of the spaces between the active device 161a and the dummy device 161b on the capping layer pattern 172 may be filled with the buried layer pattern 174, and an upper portion may be filled with the first insulating stopper layer 182. The first insulating stopper layer 182 may fill the upper portion of the spaces between the active device 161a and the dummy device 161b on the capping layer pattern 172 and cover the uppermost surface of the capping layer pattern 172. The first insulating stopper layer 182 may additionally cover a sidewall of the capping layer pattern 172, which covers a sidewall of the active device 161a or the dummy device 161b located at the outermost position from among the active devices 161a and the dummy devices 161b.

The first insulating stopper layer 182 may include an insulating material that has a dielectric constant that is higher than that of silicon oxide but a dielectric constant that is lower than that of silicon nitride. In embodiments of the present inventive concept, the first insulating stopper layer 182 may include an insulating material other than oxide.

A bit line 192B that extends while being disposed on the upper surfaces of the active device 161a and the dummy device 161b may be formed on the capping layer patterns 172, the buried layer patterns 174, the active device 161a, and the dummy device 161b. For example, the bit line 192 may be in contact with the upper surfaces of the active device 161a and the dummy device 161b. The bit line 192B may be disposed on the upper electrode 170 of the active device 161a. For example, the bit line 192B may be in contact with the upper electrode 170 of the active device 161a. The bit line 192B may have a structure in which a barrier metal layer and a metal layer are stacked on each other. The barrier metal layer may include, for example, titanium, titanium nitride, tantalum, and tantalum nitride. The metal layer may include copper, tungsten, and aluminum. The bit line 192B may extend in a second horizontal direction (Y direction). A plurality of bit lines 192B may be provided parallel to each other in the first horizontal direction (X direction).

In the second area, a third inter-wiring insulating layer 178 may be formed on the separating insulation layer 150. For example, at least a portion of the third inter-wiring insulating layer 178 may be located at substantially the same vertical level as the buried layer pattern 174. For example, the buried layer pattern 174 may be located at substantially the same vertical level as a portion of the third inter-wiring insulating layer 178. For example, the uppermost end of the third inter-wiring insulating layer 178 may be located at a higher vertical level than the uppermost end of the buried layer pattern 174, and the lowermost end of the third inter-wiring insulating layer 178 may be located at a lower vertical level than the lowermost end of the buried layer pattern 174. In embodiments of the present inventive concept, the uppermost end of the third inter-wiring insulating layer 178 may be located at substantially the same vertical level as the uppermost end of the first insulating stopper layer 182, and the lowermost end of the third inter-wiring insulating layer 178 may be located at substantially the same vertical level as the uppermost surface of the separating insulation layer 150. For example, at least a portion of the third inter-wiring insulating layer 178 may be located at substantially the same vertical level as the active device 161a and the dummy device 161b. The active device 161a and the dummy device 161b may be located at substantially the same vertical level as a portion of the third inter-wiring insulating layer 178.

The third inter-wiring insulating layer 178 may include an insulating material with a dielectric constant that is lower than that of the buried layer pattern 174. For example, the third inter-wiring insulating layer 178 may include an insulating material with a dielectric constant that is lower than that of silicon oxide. In embodiments of the present inventive concept, the third inter-wiring insulating layer 178 may include a ULK film or an ELK film.

A second wiring line 192L and a second wiring contact 192C may be formed to pass through a second insulating stopper layer 184, of the insulating stopping structure 180, the third inter-wiring insulating layer 178, and the separating insulation layer 150 and may be connected to the first wiring contact 146. For example, the second wiring line 192L may be formed to pass through the second insulating stopper layer 184 and pass through an upper portion of the third inter-wiring insulating layer 178. The second wiring contact 192C may be connected to the second wiring line 192L, and may be formed to pass through a lower portion of the third inter-wiring insulating layer 178. In addition, the second wiring contact 192C may be formed to pass through the separating insulation layer 150, and may be in contact with the first wiring contact 146. The second wiring line 192L and the second wiring contact 192C may include the same material as the bit line 192B. The second wiring line 192L and the second wiring contact 192C may have a structure in which a barrier metal layer and a metal layer are stacked on each other. For example, the second wiring line 192L and the second wiring contact 192C may be integrally connected to each other such that they form a single body. In embodiments of the present inventive concept, the upper surface of the first insulating stopper layer 182, the upper surface of the bit line 192B, the upper surface of the second wiring line 192L, the upper surface of the second insulating stopper layer 184, and the uppermost surface of the third inter-wiring insulating layer 178 may be located at substantially the same vertical level, that is, the third vertical level, thereby being substantially coplanar with each other.

A third insulating stopper layer 186 of the insulating stopping structure 180 may be disposed on the first insulating stopper layer 182, the bit line 192B, the second wiring line 192L, the second insulating stopper layer 184, and the third inter-wiring insulating layer 178. A fourth inter-wiring insulating layer 194 may be disposed on the third insulating stopper layer 186. A third wiring line 198 and a third wiring contact 196 may be disposed in the fourth inter-wiring insulating layer 194, and the third wiring line 198 may be electrically connected to the bit line 192B through the third wiring contact 198, which contacts the bit line 192B.

FIGS. 8B to 8D are enlarged views of area A of FIG. 8A according to embodiments of the present inventive concept.

FIG. 8B will be described with reference to FIGS. 1A to 8A. The active device 161a and the dummy device 161b may have a tapered shape, which has a horizontal width that decreases as the distance from the substrate W in the vertical direction (Z direction) increases, and the active device 161a and the dummy device 161b may have the greatest length from among lengths in the horizontal direction at a bottom surface of the active device 161a and the dummy device 161b. According to an embodiment of the present inventive concept, the active device 161a may have the greatest length WT_161a from among lengths in a first horizontal direction (the X direction), and the dummy device 161b may have the greatest length WT_161b from among lengths in the first horizontal direction (the X direction).

A horizontal width of the capping pattern 172 and the buried layer pattern 174, which is adjacent to the greatest length WT_161a of the active device 161a and the greatest length WT_161b of the dummy device 161b, may be a spacing SP. The spacing SP may be a spacing between the active device 161a and the dummy device 161b.

Referring to FIG. 8D, the first memory device 161 may also have a tapered shape, which has a horizontal width that decreases as the distance from the substrate W in the vertical direction (Z direction) increases and may have the greatest length in a horizontal direction. According to an embodiment of the present inventive concept, the first memory device 161 may have the greatest length WT_161 from among the lengths in the first horizontal direction X. A width in the horizontal direction of the capping pattern 174 and the buried layer pattern 174 located between the plurality of first memory devices 161 is defined as spacing SP, like in FIG. 8B. A spacing between the active device 161a and the dummy device 161b in a first horizontal direction X, that is, the spacing SP, may be substantially constant. The spacings SP in FIG. 8D may also be substantially constant. A spacing between the active device 161a and the dummy device 161b in the first horizontal direction X may be substantially equal to a spacing between the first memory devices 161 in the first horizontal direction X. For example, the spacing SP in FIG. 8B and the spacing SP in FIG. 8D may have the same width.

The greatest length WT_161a of the active device 161a may be less than the greatest length WT_161 from among the lengths of the first memory device 161 of FIG. 8D in the first horizontal direction X. The greatest length WT_161b from among the lengths of the dummy device 161b in the first horizontal direction X may be greater than the greatest length WT_161 from among the lengths of the first memory device 161 in the first horizontal direction X. For example, the spacing SP may be maintained the same in both FIGS. 8B and 8D, and as the greatest length WT_161a of the active device 161a is shortened, the greatest length WT_161b of the dummy device 161b may be increased. The greatest length WT_161b of the dummy device 161b may be greater than the greatest length WT_161a of the active device 161a. The greatest length WT_161a from among the lengths of the active device 161a in the first horizontal direction X may be about 10 nm to about 20 nm.

Referring to FIG. 8C, the greatest length WT_161a of the active device 161a may be less than the greatest length WT_161 from among the lengths of the first memory device 161 of FIG. 8D in the first horizontal direction X. The greatest length WT_161b from among the lengths of the dummy device 161b in the first horizontal direction X may be less than the greatest length WT_161 from among the lengths of the first memory device 161 in the first horizontal direction X. As the greatest length WT_161a of the active device 161a and the greatest length WT_161b of the dummy device 161b are each less than the greatest length WT_161 from among the length of the first memory device 161 of FIG. 8D in the first horizontal direction X, the buried layer pattern 174 may be moved in the first horizontal direction X and may be located between the active device 161a and the first dummy device 161b. For example, the spacing SP may be maintained the same in both FIGS. 8C and 8D.

Referring to FIG. 8D, each of the lower electrode contacts 152 may be disposed on the lower surface of the first memory device 161. Each of the lower electrode contacts 152 may be connected to the first wiring contact 146.

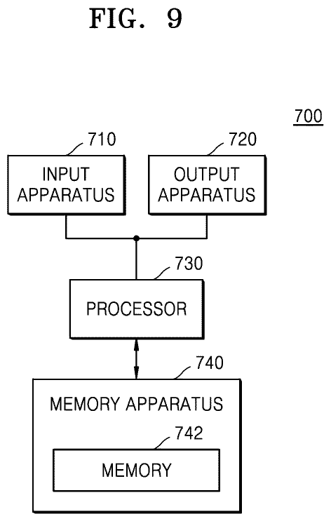

FIG. 9 is a block diagram of an information processing system including a magnetic memory apparatus according to an embodiment of the present inventive concept.

Referring to FIG. 9, an information processing system 700 includes an input apparatus 710, an output apparatus 720, a processor 730, and a memory apparatus 740. In embodiments of the present inventive concept, the memory apparatus 740 may include a cell array including a non-volatile memory cell and a peripheral circuit for an operation such as read/write operation. In embodiments of the present inventive concept, the memory apparatus 740 may include a non-volatile memory apparatus and a memory controller.

A memory 742 provided in the memory apparatus 740 may include a magnetic tunnel junction (MTJ) 168 or the magnetic memory apparatus 100 including an MTJ according to the embodiments described with reference to FIGS. 1 to 8D.

The processor 730 may be connected to the input apparatus 710, the output apparatus 720, and the memory apparatus 740 through an interface and may control the overall operation of the information processing system 700.

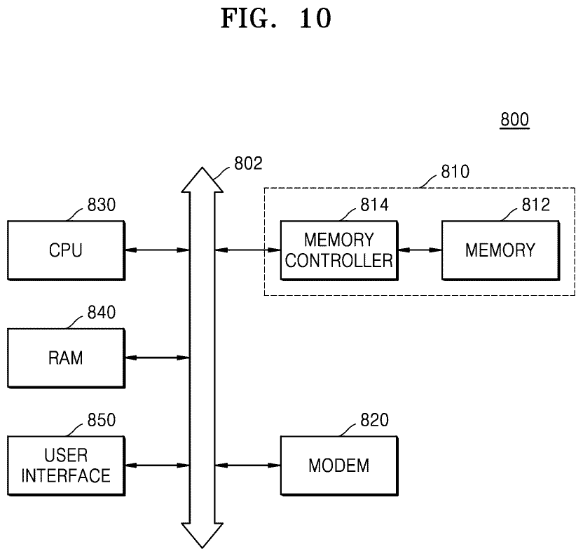

FIG. 10 is a block diagram of an electronic system including a magnetic memory apparatus according to an embodiment of the present inventive concept.

Referring to FIG. 10, an electronic system 800 includes a non-volatile memory system 810, a MODEM 820, a central processing apparatus 830, a RAM 840, and a user interface 850 that are electrically connected to a bus 802.

The non-volatile memory system 810 may include a memory 812 and a memory controller 814. The non-volatile memory system 810 stores data that is processed by the central processing apparatus 830 or data that is input from the outside.

The non-volatile memory system 810 may include a non-volatile memory such as MRAM, PRAM, RRAM, and FRAM. At least one of the memory 812 and the RAM 840 may include the MTJ 168 or the magnetic memory apparatus 100 including an MTJ according to the embodiments described with reference to FIGS. 1 to 8D.

The electronic system 800 may be used in, for example, a portable computer, a web tablet, a wireless phone, a mobile phone, a digital music player, a memory card, an MP3 player, a navigation device, a portable multimedia player (PMP), a solid state disk (SSD), or household appliances. However, the present inventive concept is not limited thereto.

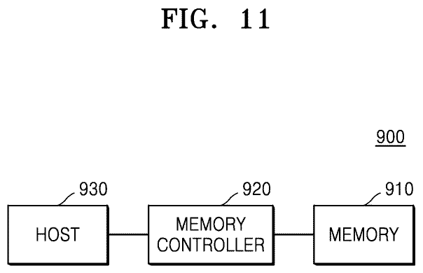

FIG. 11 is a block diagram of a memory card including a magnetic memory apparatus according to an embodiment of the present inventive concept.

Referring to FIG. 11, a memory card 900 includes a memory 910 and a memory controller 920.

The memory 910 may store data. In embodiments of the present inventive concept, the memory 910 has non-volatile characteristics by which stored data is retained even if power supply is interrupted or terminated. The memory 910 may include the MTJ 168 or the magnetic memory apparatus 100 including a MTJ according to the embodiments described with reference to FIGS. 1 to 8D.

The memory controller 920 may read data that is stored in the memory 910 or store data in the memory 910 in response to a read/write request from a host 930.

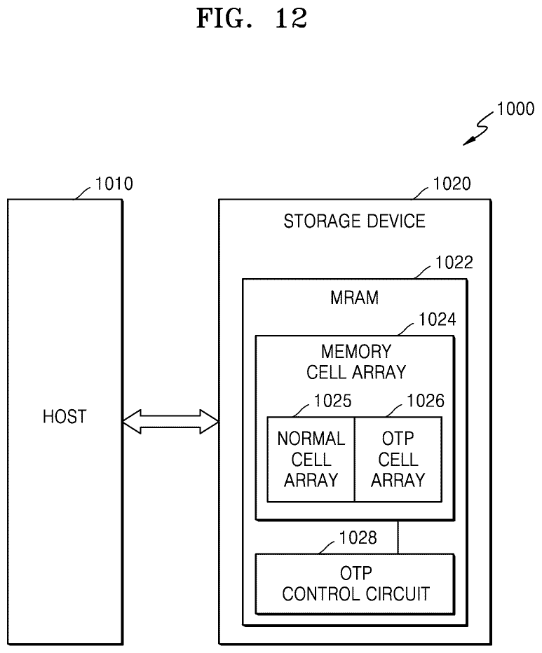

FIG. 12 is a block diagram of an electronic apparatus including a magnetic memory apparatus according to an embodiment of the present inventive concept.

Referring to FIG. 12, an electronic device 1000 includes a host 1010 and a storage device 1020.

The host 1010 may include a user apparatus, for example, a personal computer, a portable computer, a tablet PC, a smartphone, a digital camera, and a camcorder. The host 1010 stores data in or reads data from the storage device 1020 through an input/output request.

The host 1010 may be connected to the storage device 1020 through various interfaces such as a universal serial bus (USB), a multimedia card (MMC), a peripheral component interconnection (PCI), a PCI-express (PCI-E), an advanced technology attachment (ATA), a serial-ATA, a parallel-ATA, a small computer small interface (SCSI), an Enhanced Small Disk Interface (ESDI), and integrated drive electronics (IDE).

The storage device 1020 may be a data storage for performing a write operation or a read operation according to an input/output request from the host 1010 and may include a magnetic memory apparatus 1022. The magnetic memory apparatus 1022 includes a memory cell array 1024 and an OTP control circuit 1028, and the memory cell array 1024 includes a normal memory cell array 1025 and an OTP memory cell array 1026.

Normal memory cells including a first selection transistor and a first variable resistance device are arranged in the normal memory cell array 1025, and bit lines of the normal memory cells are provided to a sense amplifier. OTP memory cells including a second selection transistor and a short-circuited second variable resistance device are arranged in the OTP memory cell array 1026, and OTP bit lines of the OTP memory cells are provided to the sense amplifier.

The OTP control circuit 1028 generates a reference resistance instead of the short-circuited second variable resistance device of the OTP memory cell and provides the reference resistance to the OTP bit line. The sense amplifier detects and amplifies a current that flows in the OTP bit line of the OTP memory cell, to which the bit line of the normal memory cell and a reference resistor are connected, thereby increasing a sensing margin of the normal memory cell.

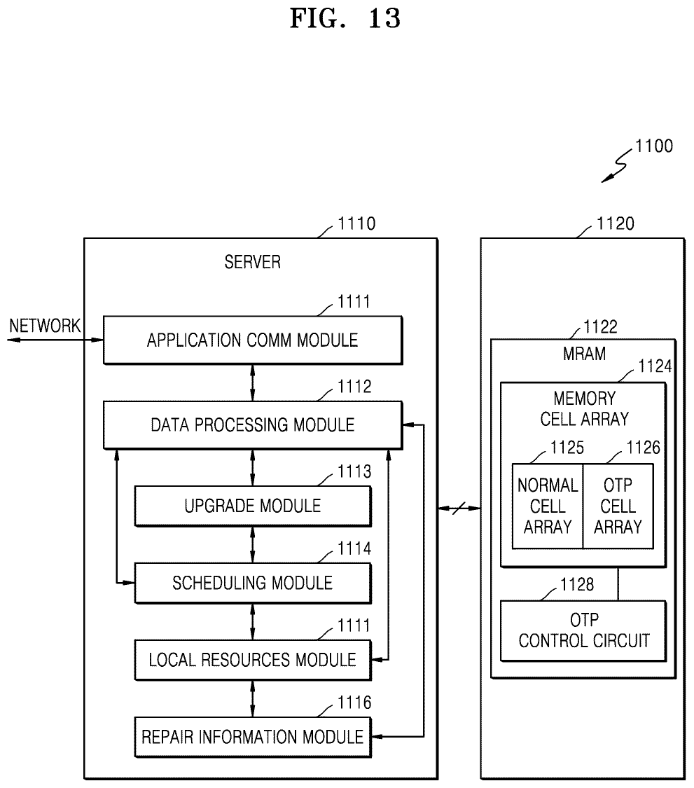

FIG. 13 is a block diagram of a server system including a magnetic memory apparatus according to an embodiment of the present inventive concept.

Referring to FIG. 13, a server system 1100 includes a server 1110 and at least one storage device 1120 that stores data that is for operating the server 1110.

The server 1110 includes an application communication module 1111, a data processing module 1112, an upgrade module 1113, a schedule module 1114, a local resource module 1115, and a repair information module 1116. The application communication module 1111 is implemented to communicate with the server 1110 and a computing system connected to a network or to communicate between the server 1110 and the storage device 1120. The application communication module 1111 transmits data or information provided through the user interface to the data processing module 1112.

The data processing module 1112 is linked to the local resource module 1115. The local resource module 1115 provides a list of repair shops/dealers/technical information based on data or information connected to the server 1110. The upgrade module 1113 interfaces with the data processing module 1112. The upgrade module 1113 upgrades firmware, reset code, diagnostic system upgrade, or other information to an electronic product based on data or information transmitted from the storage device 1120.

The schedule module 1114 allows real-time options to a user based on data or information input to the server 1110. The repair information module 1116 interfaces with the data processing module 1112. The repair information module 1116 is used to provide repair-related information, for example, audio, video, or document files to the user. The data processing module 1112 packages related information based on information transmitted from the storage device 1120. This information is transmitted to the storage device 1120 or displayed to the user. The storage device 1120 may include the magnetic memory apparatus 1122 as a data storage.

The magnetic memory apparatus 1122 includes a memory cell array 1124 and an OTP control circuit 1128, and the memory cell array 1124 includes a normal memory cell array 1125 and an OTP memory cell array 1126.

Normal memory cells including a first selection transistor and a first variable resistance device are arranged in the normal memory cell array 1125, and bit lines of the normal memory cells are provided to the sense amplifier. OTP memory cells including a second selection transistor and a short-circuited second variable resistance device are arranged in the OTP memory cell array 1126, and OTP bit lines of the OTP memory cells are provided to the sense amplifier.

The OTP control circuit 1128 generates a reference resistance instead of the short-circuited second variable resistance device of the OTP memory cell and provides the reference resistance to the OTP bit line. The sense amplifier detects and amplifies a current that flows in the OTP bit line of the OTP memory cell, to which the bit line of the normal memory cell and a reference resistor are connected, thereby increasing a sensing margin of the normal memory cell.

The embodiments of the present inventive concept described above are merely illustrative, and various modifications and other equivalent embodiments may be made by those skilled in the art.

As is traditional in the field of the inventive concepts, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of the inventive concepts. Further, the blocks, units and/or modules of the embodiments may be physically combined into more complex blocks, units and/or modules without departing from the scope of the inventive concepts.

While the present inventive concept has been described with reference to embodiments thereof, it will be understood by those of ordinary skill in the art that various changes in form and details may be made thereto without departing from the spirit and scope of the present inventive concept.

What is claimed is:

1. A magnetic memory apparatus comprising:
a plurality of bit lines;
a plurality of source lines arranged at a different vertical level from the plurality of bit lines; and
a plurality of memory cells connected between the bit lines and the source lines and each including a memory device and a selection transistor,
wherein each of the plurality of memory cells includes a first memory cell, which includes a first memory device, and a second memory cell, which includes a second memory device,
each of the first memory device and the second memory device includes a magnetic tunnel junction including a pinned layer, a tunnel barrier layer, and a free layer,
in some of the second memory devices, the magnetic tunnel junction has an irreversible resistance state due to insulation breakdown of the tunnel barrier layer,
each of the second memory devices includes a first dummy device, a second dummy device, and an active device located between the first dummy device and the second dummy device, and
a spacing between the first dummy device and the active device in a first horizontal direction is substantially equal to a spacing between the second dummy device and the active device.

2. The magnetic memory apparatus of claim 1, wherein the spacing between the active device and the second dummy device in the first horizontal direction is substantially equal to a spacing between the first memory devices in the first horizontal direction.

3. The magnetic memory apparatus of claim 1, wherein a greatest length of the active device in the first horizontal direction is less than a greatest length from among lengths of the first memory devices in the first horizontal direction.

4. The magnetic memory apparatus of claim 3, wherein a greatest length of the first dummy device in the first horizontal direction is less than a greatest length from among lengths of the first memory devices in the first horizontal direction.

5. The magnetic memory apparatus of claim 3, wherein a greatest length of the first dummy device in the first horizontal direction is greater than a greatest length from among lengths of the first memory devices in the first horizontal direction.

6. The magnetic memory apparatus of claim 3, wherein a greatest length of the active device in the first horizontal direction ranges from about 10 nm to about 20 nm.

7. The magnetic memory apparatus of claim 1, further comprising word lines extending in the first horizontal direction,
wherein the source lines are electrically connected to the bit lines, respectively.

8. The magnetic memory apparatus of claim 1, wherein the first dummy device is not connected to the source line, and
the active device is connected to the source line by a metal wiring.

9. The magnetic memory apparatus of claim 1, wherein the first memory cells constitute a normal memory cell array to be programmed multiple times, and
the second memory cells constitute a one time programmable (OTP) memory cell array to be programmed once.

10. The magnetic memory apparatus of claim 9, wherein a number of selection transistors per unit memory cell is greater in the second memory cell than the first memory cell.

11. A magnetic memory apparatus comprising:
a substrate having a first area and a second area;
a plurality of first memory devices and a plurality of second memory devices that each constitute a memory cell and are spaced apart from each other in a first horizontal direction, in the first area;
an inter-wiring insulating layer located in the second area and having at least a portion located at a substantially same vertical level as the first memory devices and the second memory devices;
capping layer patterns covering sidewalls of the plurality of first memory devices and the second memory devices; and
buried layer patterns covering the capping layer patterns and filling a portion of each of spaces between the plurality of first memory devices and between the plurality of second memory devices, in the first area,
wherein each of the plurality of first memory devices and the plurality of second memory devices includes a magnetic tunnel junction including a pinned layer, a tunnel barrier layer, and a free layer,
in some of the plurality of second memory devices, the magnetic tunnel junction has an irreversible resistance state due to insulation breakdown of the tunnel barrier layer,
each of the second memory devices each includes a first dummy device, a second dummy device, and an active device located between the first dummy device and the second dummy device,
a spacing between the first dummy device and the active device in the first horizontal direction is substantially equal to a spacing between the second dummy device and the active device, and
the spacing between the active device and the first dummy device in the first horizontal direction is substantially equal to a spacing between the plurality of first memory devices in the first horizontal direction.

12. The magnetic memory apparatus of claim 11, wherein a greatest length of the active device in the first horizontal direction is less than a greatest length from among lengths of the first memory devices in the first horizontal direction.

13. The magnetic memory apparatus of claim 12, wherein a greatest length of the first dummy device in the first horizontal direction is less than a greatest length from among lengths of the first memory devices in the first horizontal direction.

14. The magnetic memory apparatus of claim 12, wherein a greatest length of the first dummy device in the first horizontal direction is greater than a greatest length from among lengths of the first memory devices in the first horizontal direction.

15. The magnetic memory apparatus of claim 11, further comprising word lines extending in the first horizontal direction,
wherein the memory cell further includes a selection transistor,
the memory cell is connected between bit lines and source lines, and
the source lines are located at a different vertical level from the bit lines.

16. The magnetic memory apparatus of claim 11, wherein at least one of the magnetic tunnel junction or a selection transistor, constituting the dummy device, is not connected to a metal wiring.

17. The magnetic memory apparatus of claim 16, wherein the metal wiring includes:
a plurality of wiring lines electrically connected to the selection transistor; and
a plurality of wiring contacts located on the plurality of wiring lines,
the active device is electrically connected to at least three wiring contacts of the plurality of wiring contacts, and
each of the plurality of first memory devices is electrically connected to one wiring contact of the plurality of wiring contacts.

18. The magnetic memory apparatus of claim 11, wherein the first area includes a cell array area, and the second area includes a peripheral circuit area.

19. A magnetic memory apparatus comprising:
a substrate having a cell array area and a peripheral circuit area;
a separating insulation layer located in the cell array area and the peripheral circuit area;
a plurality of first memory devices and a plurality of second memory devices that are located on the separating insulation layer in the cell array area, wherein the plurality of first memory devices and the plurality of second memory devices constitute a plurality of memory cells, and are spaced apart from each other in a horizontal direction;
an inter-wiring insulating layer located in the peripheral circuit area and having at least a portion located at a substantially same vertical level as the plurality of first memory devices and the plurality of the second memory devices;
capping layer patterns covering sidewalls of the plurality of first memory devices and the plurality of second memory devices; and
buried layer patterns covering the capping layer patterns and filling a portion of each of spaces that are between the plurality of first memory devices and between the plurality of second memory devices, in the cell array area,
wherein each of the plurality of first memory devices and the plurality of second memory devices includes a magnetic tunnel junction including a pinned layer, a tunnel barrier layer, and a free layer,
in some of the plurality of second memory devices, the magnetic tunnel junction has an irreversible resistance state due to insulation breakdown of the tunnel barrier layer,
each of the plurality of second memory devices includes a first dummy device, a second dummy device, and an active device located between the first dummy device and the second dummy device,
a spacing between the first dummy device and the active device in a first horizontal direction is substantially equal to a spacing between the second dummy device and the active device,
the spacing between the active device and the first dummy device in the first horizontal direction is substantially equal to a spacing between the plurality of first memory devices in the first horizontal direction,
a greatest length of the active device in the first horizontal direction is less than a greatest length of the first memory devices in the first horizontal direction, and
a greatest length of the first dummy device in the first horizontal direction is less than a greatest length from among lengths of the first memory devices in the first horizontal direction.

20. The magnetic memory apparatus of claim 19, wherein at least one of the magnetic tunnel junction or a selection transistor, constituting the dummy device, is not connected to a metal wiring,
the metal wiring includes a plurality of wiring lines electrically connected to the selection transistor, and a plurality of wiring contacts located on the plurality of wiring lines,
the active device is electrically connected to at least three wiring contacts of the plurality of wiring contacts, and
each of the plurality of first memory devices is electrically connected to one wiring contact of the plurality of wiring contacts.
